(19) United States
(12) Patent Application Publication
(10) Pub. No.: US 2026/0198360 A1
(43) Pub. Date: Jul. 9, 2026

(54) METHOD FOR PRODUCING AN ELECTRONIC COMPONENT

(71) Applicant: ams-OSRAM International GmbH, Regensburg (DE)

(72) Inventors: Thomas Schwarz, Regensburg (DE); Klaus Müller, Pettendorf (DE)

(21) Appl. No.: 19/129,599

(22) PCT Filed: Nov. 14, 2023
(86) PCT No.: PCT/EP2023/081683

§ 371 Date: May 13, 2025

(30) Foreign Application Priority Data
Nov. 22, 2022 (DE) 10 2022 130 878.2

(51) Int. Cl. H10W 72/00; H10W 72/30; H10W 72/90

(52) U.S. Cl. CPC H10W 72/07355; H10W 72/07352; H10W 72/322; H10W 72/352; H10W 72/952

(57) ABSTRACT

In an embodiment, a method includes providing an electronic semiconductor chip having a contact pad with a layer having gold, providing a carrier having a mating contact pad, arranging capsules on the mating contact pad, wherein each of the capsules comprises a solid shell, which surrounds a supercooled metallic liquid, and wherein the supercooled metallic liquid comprising tin, arranging the electronic semiconductor chip on the carrier such that the contact pad faces the mating contact pad and opening the capsules, wherein the supercooled metallic liquid wets the mating contact pad and the contact pad, and wherein the tin and the gold form an intermetallic compound.

### CROSS-REFERENCE TO RELATED APPLICATIONS

This patent application is a national phase filing under section 371 of PCT/EP2023/081683, filed Nov. 14, 2023, which claims the priority of German patent application no. 10 2022 130 878.2, filed Nov. 22, 2022, each of which is incorporated herein by reference in its entirety.

### TECHNICAL FIELD

The present invention relates to a method for producing an electronic component.

### BACKGROUND

The use of AuSn soldered connections for producing electronic components is known. With known methods, the production of such soldered connections involves a high temperature, which in the case where the components connected to one another have different coefficients of thermal expansion may result in severe mechanical strains.

### SUMMARY

Embodiments provide a method for producing an electronic component.

A method for producing an electronic component comprises steps for providing an electronic semiconductor chip having a contact pad having a layer which comprises gold, for providing a carrier having a mating contact pad, for arranging capsules on the mating contact pad, where the capsules each comprise a solid shell which surrounds a supercooled metallic liquid, with the supercooled metallic liquid comprising tin for arranging the electronic semiconductor chip on the carrier in such a way that the contact pad faces the mating contact pad, and for opening the capsules, where the supercooled metallic liquid wets the mating contact pad and the contact pad, with tin and gold forming an intermetallic compound.

This method allows a soldered connection to be produced between the contact pad of the electronic semiconductor chip and the mating contact pad of the carrier. The soldered connection here may advantageously be produced at a low temperature, more particularly at a temperature which is lower than the melting temperature of the intermetallic compound. As a result, the method advantageously allows soldered connections to be produced with only a low level of mechanical strains, even in the case where the components connected to one another have different coefficients of thermal expansion.

In one embodiment of the method, the opening of the capsules is followed by a further method step for heat-treating the electronic semiconductor chip and the carrier. The heat treatment may, for example, increase the quality and homogeneity of the soldered connection produced with the aid of the method.

In one embodiment of the method, the heat treatment takes place at a temperature of between 150° C. and 180° C. As a result of this comparatively low temperature, advantageously, only a low level of mechanical strains are generated in the soldered connection generated by the method.

In one embodiment of the method, the intermetallic compound is formed at a temperature of less than 200° C. For example, the intermetallic compound may be formed at a temperature of 180° C. As a result, advantageously, only a low level of mechanical strains are generated in the soldered connection produced by the method.

In one embodiment of the method, the electronic semiconductor chip is arranged on the carrier using a heatable tool. The heatable tool may be, for example, a heated bond head. Using a heatable tool makes it possible simultaneously to position the electronic semiconductor chip on the carrier and to heat it to a temperature sufficient to produce the intermetallic compound.

In one embodiment of the method, the capsules are opened by pressing the electronic semiconductor chip against the carrier, in particular with a pressure of between 0.05 kgf/mm² and 0.2 kgf/mm² . The electronic semiconductor chip may be pressed against the carrier using, for example, the tool used for arranging the electronic semiconductor chip on the carrier. As a result, advantageously, controlled and reliable opening of the capsules is achieved.

In one embodiment of the method, the capsules are opened by dissolving the solid shells, for example by an etching method, for example in an atmosphere comprising formic acid. This also has the effect, advantageously, of achieving controlled and reliable opening of the capsules. An advantage of this embodiment is that it permits simultaneous opening of capsules arranged on multiple mating contact pads of the carrier.

In one embodiment of the method, the capsules are arranged by spray application using a mask, by a printing method using a printing screen or a printing stencil, by centrifugal application or by contactless needle dispensing. Through these methods it becomes possible to limit the arrangement of the capsules to the mating contact pad of the carrier.

In one embodiment of the method, the capsules for arranging on the mating contact pad are dissolved in a solvent. The solvent evaporates after the arranging of the capsules. The solvent may advantageously facilitate the arranging of the capsules on the mating contact pad of the carrier.

In one embodiment of the method, a layer thickness of the gold-comprising layer and an amount of the capsules arranged on the mating contact pad are dimensioned such that the amount-of-substance fraction of gold in the intermetallic compound formed is at least 60%. In this case, the intermetallic compound formed by the method has favorable mechanical properties.

In one embodiment of the method, the gold-comprising layer has a layer thickness of between 1 μm and 3 μm, more particularly a layer thickness of between 1 μm and 2 μm. The gold-comprising layer may have, for example, a layer thickness of 1.5 μm. Advantageously, this enables the production of an intermetallic compound having a favorable amount-of-substance fraction of gold.

In one embodiment of the method, the capsules are applied as a layer having a layer thickness of between 1 μm 5 μm, more particularly having a layer thickness of between 2 μm and 3 μm. A layer thickness of this kind for the capsules advantageously enables production of an intermetallic compound having a favorable amount-of-substance fraction of tin.

In one embodiment of the method, the capsules are applied as a monolayer. In this case, advantageously, particularly uniform wetting of the mating contact pad and of the contact pad by the supercooled metallic liquid can be achieved.

In one embodiment of the method, the electronic semiconductor chip is an optoelectronic semiconductor chip. The electronic semiconductor chip may, for example, be a light-emitting diode chip (LED chip).

In one embodiment of the method, the carrier is a QFN chip housing. In this case, components of the carrier and components of the electronic semiconductor chip may have significantly different coefficients of thermal expansion. Nevertheless, advantageously, the method enables production of a soldered connection having only low levels of mechanical strains.

### BRIEF DESCRIPTION OF THE DRAWINGS

The above-described properties, features and advantages of this invention, and the manner in which they are achieved, become more clearly and distinctly comprehensible in connection with the following description of the exemplary embodiments, which are elucidated in more detail in connection with the drawings. In the latter, in a schematized representation in each case,

FIG. 1 shows a side view, in section, of an electronic semiconductor chip with a contact pad;

FIG. 2 shows a side view, in section, of a carrier with a mating contact pad;

FIG. 3 shows capsules, in solution in a solvent, which are arranged on the mating contact pad using a mask;

FIG. 4 shows the capsules arranged on the mating contact pad after the evaporation of the solvent;

FIG. 5 shows a plan view of the mating contact pad with the capsules arranged thereon;

FIG. 6 shows an arranging of the electronic semiconductor chip on the carrier;

FIG. 7 shows a wetting of the contact pad and of the mating contact pad by a supercooled metallic liquid contained in the capsules, after the opening of the capsules;

FIG. 8 shows a soldered connection formed by an intermetallic compound between the contact pad and the mating contact pad; and

FIG. 9 shows a plan view of an electronic component formed by the carrier and the electronic semiconductor chip.

### DETAILED DESCRIPTION OF ILLUSTRATIVE EMBODIMENTS

FIG. 1 shows a schematic side view, in section, of an electronic semiconductor chip 100. The electronic semiconductor chip 100 comprises a front side 101 and a contact side 102 situated opposite the front side 101.

The electronic semiconductor chip 100 may be, for example, an optoelectronic semiconductor chip—for example, a light-emitting diode chip (LED chip). In this case, the front side 101 of the electronic semiconductor chip 100 may be intended for light emission.

Configured on the contact side 102 of the electronic semiconductor chip 100 is a contact pad 110. The contact pad 110 is intended for electrical, mechanical and thermal contacting of the electronic semiconductor chip 100 via a soldered connection. As well as this contact pad 110, the electronic semiconductor chip 100 may comprise further contact pads for electrical contacting, which may be arranged on the contact side 102 or on the front side 101 of the electronic semiconductor chip 100. In the example shown in FIG. 1, the electronic semiconductor chip 100 comprises a further contact pad on its front side 101.

On the contact pad 110, a layer 120 comprising gold is arranged on the contact side 102 of the electronic semiconductor chip 100. The layer 120 has a layer thickness 125 which may be, for example, between 1 μm and 3 μm, more particularly between 1 μm and 2 μm. For example, the layer thickness 125 of the layer 120 may be 1.5 μm. Beneath the gold-comprising layer 120, there may be further layers configured on the contact pad 110 of the electronic semiconductor chip 100, examples being one or more metallic layers of low solubility—for example, layers comprising nickel (Ni), palladium (Pd) or platinum (Pt). In each case, however, the gold-comprising layer 120 forms the outermost layer of a layer stack of this kind.

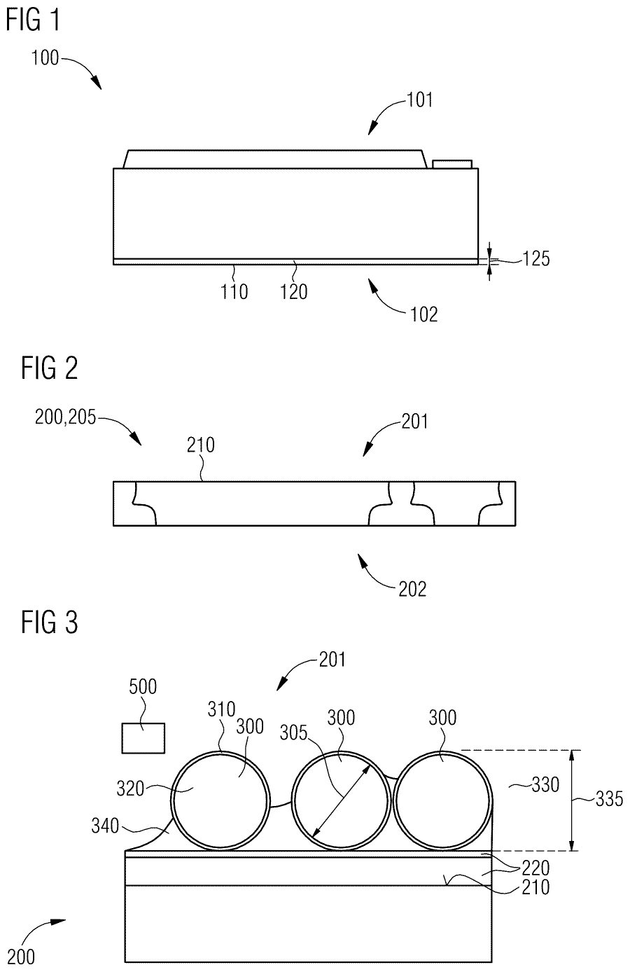

FIG. 2 shows a schematic side view, in section, of a carrier 200. The carrier 200 may also be referred to as the substrate. The carrier 200 may be configured, for example, as a ceramic carrier, as a printed circuit board (PCB), as a semiconductor chip or as a different carrier. In the example represented in FIG. 2, the carrier 200 is embodied as a QFN chip housing 205 having leadframe portions embedded in a polymeric material.

The carrier 200 comprises a top side 201 and a bottom side 202 situated opposite the top side 201. A mating contact pad 210 is configured on the top side 201 of the carrier 200. The mating contact pad 210 is intended for electrically conducting connection to the contact pad 110 of the electronic semiconductor chip 100 by way of a soldered connection.

FIG. 3 shows an enlarged side view, in section, of a part of the mating contact pad 210 configured on the top side 201 of the carrier 200. Configured on the mating contact pad 210 is a coating 220, which in the example represented comprises a metallic layer of low solubility and a layer covering this layer and composed of a readily wettable metal. The layer of low solubility may comprise nickel, palladium or platinum, for example. The readily wettable layer may comprise gold, palladium or platinum, for example. The readily wettable layer may have a thickness, for example, of less than 200 nm.

FIG. 3 shows the carrier 200 during the performance of an operating step for arranging capsules 300 on the mating contact pad 210. The capsules 300 may have, for example, a spherical configuration and they each comprise a solid shell 310. For each capsule 300, the solid shell 310 surrounds a supercooled metallic liquid 320. The supercooled metallic liquid 320 comprises tin (Sn), which usefully is pure tin. The shell 310 may comprise a tin oxide, for example. Each of the capsules may have, for example, a diameter 305 between 0.5 μm and 10 μm, more particularly, for example, a diameter 305 of between 1 μm and 5 μm.

In the example represented in FIG. 3, the capsules 300 are arranged on the mating contact pad 210 of the carrier 200 by a spraying method using a mask 500. For this method, the capsules 300 are in solution in a solvent 340. The solvent 340 evaporates after sprayed application to the mating contact pad 210 of the carrier 200, and so only the capsules 300 remain on the mating contact pad 210.

Alternative options for arranging the capsules 300 on the mating contact pad 210 are a printing method using a printing screen or a printing stencil, centrifugal application, or application by contactless needle dispensing (jetting). With these methods too, the capsules 300 may initially be in solution in a solvent, which subsequently evaporates.

The capsules 300 are arranged as a layer 330 on the mating contact pad 210 of the carrier 200. The layer 330 has a layer thickness 335 which may be, for example, between 1 μm and 5 μm, more particularly, for example, between 2 μm and 3 μm. It may be useful if the layer 330 is a monolayer of capsules 300.

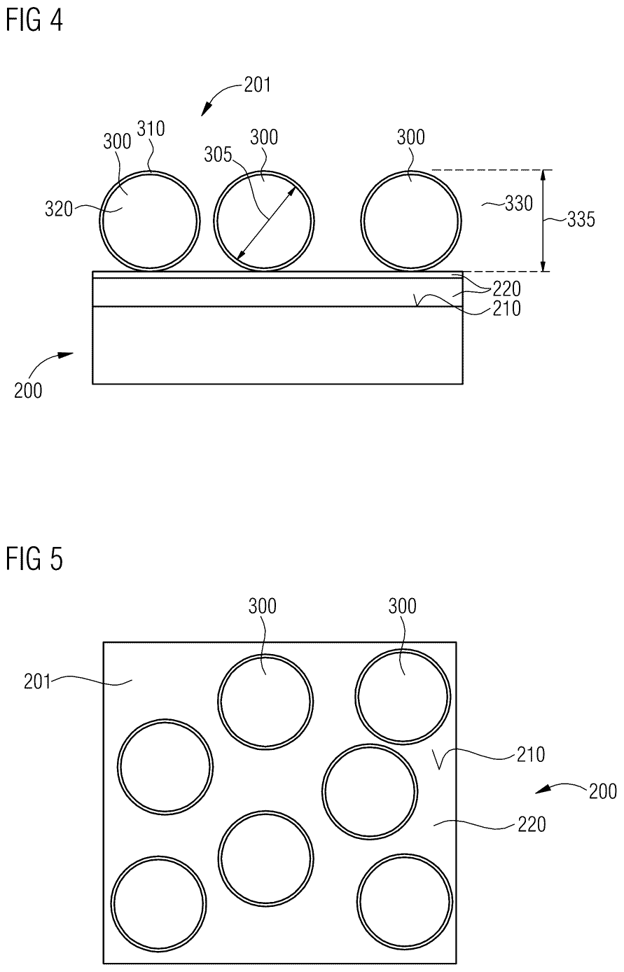

FIG. 4 shows a schematic side view, in section, of a part of the mating contact pad 210 of the carrier 200 with the capsules 300 arranged thereon, after the evaporation of the solvent 340. FIG. 5 shows a plan view of a part of the mating contact pad 210 with the capsules 300 arranged thereon.

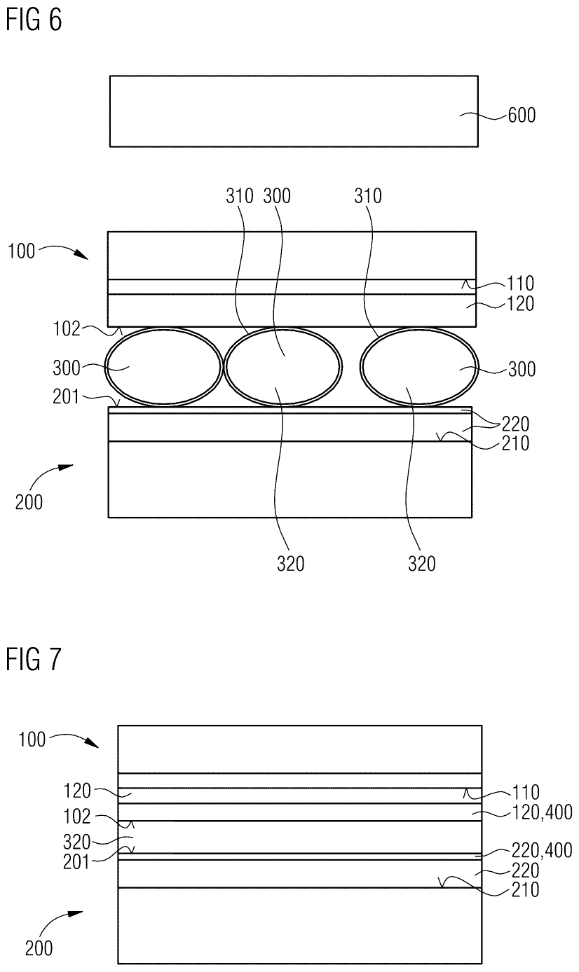

FIG. 6 shows a schematic side view, in section, of a part of the carrier 200, with the capsules 300 arranged on the mating contact pad 210, during the performance of a working step, taking place temporally after the representation in FIGS. 4 and 5, for arranging the electronic semiconductor chip 100 on the carrier 200. The electronic semiconductor chip 100 is arranged on the carrier 200 in such a way that the contact pad 110 of the electronic semiconductor chip 100 is facing the mating contact pad 210 of the carrier 200 and the capsules 300 arranged thereon.

In the example represented in FIG. 6, the electronic semiconductor chip 100 is arranged with the aid of a tool 600, which is represented only schematically. This step may be referred to as a die attach step. The tool 600 may be configured as a heatable tool (heated bond head) and may heat the electronic semiconductor chip 100, during the arranging on the carrier 200, to a specified temperature—for example, to a temperature of 180° C. At this stage, the carrier 200 may have a temperature, for example, of room temperature, being for example at a temperature of 25° C.

At the same time as or after the arranging of the electronic semiconductor chip 100 on the carrier 200, the shells 310 of the capsules 300 are opened, and so the supercooled metallic liquid 320 contained in the capsules 300 emerges. The supercooled metallic liquid 320 then wets the mating contact pad 210 of the carrier 200 and the contact pad 110 of the electronic semiconductor chip 100, with formation of an intermetallic compound 400 from the tin of the supercooled metallic liquid 320 and the gold of the layer 120 on the contact pad 110 of the electronic semiconductor chip 100. This operation is represented schematically in the side view in section of FIG. 7.

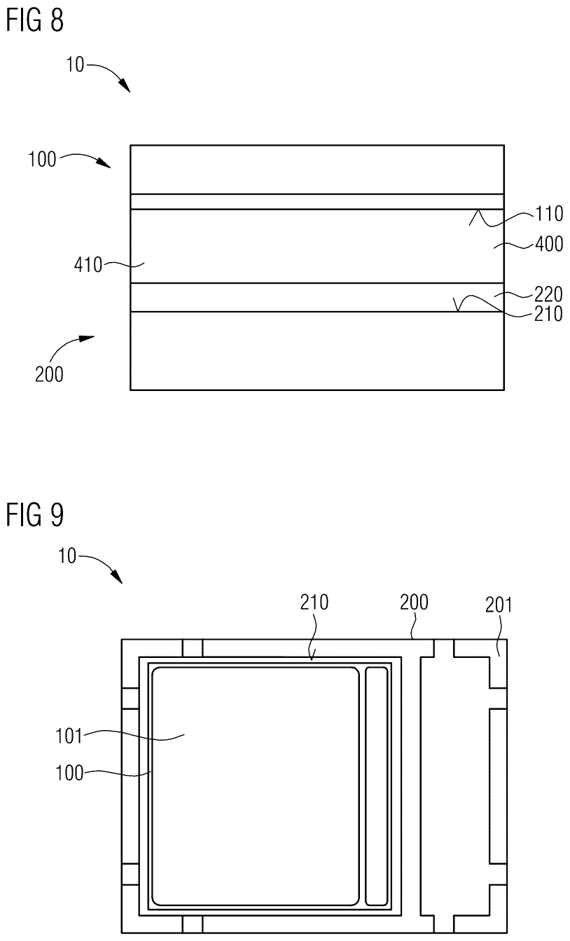

After the intermetallic compound 400 has solidified, it forms a soldered connection 410, which provides an electrically conducting connection of the contact pad 110 of the electronic semiconductor chip 100 to the mating contact pad 210 of the carrier 200. This working state is represented schematically in the side view in section of FIG. 8.

The capsules 300 may be opened by the pressing of the electronic semiconductor chip 100 against the carrier 200, with a pressure, for example, of between 0.05 kgf/mm² and 0.2 kgf/mm² . The electronic semiconductor chip 100 may be pressed against the carrier 200 using, for example, the tool 600 used to arrange the electronic semiconductor chip 100 on the mating contact pad 210 of the carrier 200. Alternatively, the electronic semiconductor chip 100 may be pressed with a different tool.

One alternative option for opening the capsules 300 is to dissolve the shells 310 of the capsules 300, by an etching method, for example. This may take place, for example, in an atmosphere comprising formic acid.

After the capsules 300 have opened and the supercooled metallic liquid 320 has emerged, a further method step may be performed for heat-treating the electronic semiconductor chip 100 and the carrier 200, to increase the quality of the intermetallic compound 400. The heat treatment may take place, for example, at a temperature of between 150° C. and 180° C. Hence the intermetallic compound 400 is formed overall at a temperature of less than 200° C.

The layer thickness 125 of the gold-comprising layer 120 on the contact pad 110 of the electronic semiconductor chip 100 and the amount of the capsules 300 arranged on the mating contact pad 210 of the carrier 200 are usefully dimensioned such that the amount-of-substance fraction (atomic percent, % at) of gold in the intermetallic compound 400 formed is at least 60%.

FIG. 9, in a schematic representation, shows a plan view of an electronic component 10 formed by the connecting of the electronic semiconductor chip 100 to the carrier 200. If the electronic semiconductor chip 100 is an optoelectronic semiconductor chip, the electronic component 10 is an optoelectronic component.

The invention has been more closely illustrated and described with reference to the preferred exemplary embodiments. Nevertheless, the invention is not confined to the examples disclosed. The skilled person is able to derive different variations.

1.-15. (canceled)

16. A method for producing an electronic component, the method comprising:
providing an electronic semiconductor chip having a contact pad with a layer comprising gold;
providing a carrier having a mating contact pad;
arranging capsules on the mating contact pad, wherein each of the capsules comprises a solid shell, which surrounds a supercooled metallic liquid, and wherein the supercooled metallic liquid comprising tin;
arranging the electronic semiconductor chip on the carrier such that the contact pad faces the mating contact pad; and
opening the capsules, wherein the supercooled metallic liquid wets the mating contact pad and the contact pad, and wherein the tin and the gold form an intermetallic compound.

17. The method according to claim 16, further comprising, after the opening of the capsules, heat-treating the electronic semiconductor chip and the carrier.

18. The method according to claim 17, wherein the heat treatment takes place at a temperature of between 150° C. and 180° C., inclusive.

19. The method according to claim 16, wherein the intermetallic compound is formed at a temperature of less than 200° C.

20. The method according to claim 16, wherein the electronic semiconductor chip is arranged using a heatable tool.

21. The method according to claim 16, wherein the capsules are opened by pressing the electronic semiconductor chip against the carrier.

22. The method according to claim 21, wherein pressing comprises a pressure of between 0.05 kgf/mm² and 0.2 kgf/mm² , inclusive.

23. The method according to claim 16, wherein the capsules are opened by dissolving the solid shells.

24. The method according to claim 23, wherein dissolving comprises etching the solid shells.

25. The method according to claim 24, wherein etching comprises an atmosphere having formic acid.

26. The method according to claim 16, wherein the capsules are arranged by spray application using a mask, by a printing method using a printing screen or a printing stencil, by centrifugal application or by contactless needle dispensing.

27. The method according to claim 16,
wherein the capsules are dissolved in a solvent, and
wherein the solvent evaporates after the arranging of the capsules.

28. The method according to claim 16,
wherein a layer thickness of the layer and an amount of the capsules arranged on the mating contact pad are dimensioned such that the amount-of-substance fraction of gold in the intermetallic compound formed is at least 60%.

29. The method according to claim 16, wherein the layer has a layer thickness of between 1 μm and 3 μm, inclusive.

30. The method according to claim 16, wherein the capsules are applied as a layer having a layer thickness of between 1 μm and 5 μm, inclusive.

31. The method according to claim 16, wherein the capsules are applied as a layer having a layer thickness of between 2 μm and 3 μm, inclusive.

32. The method according to claim 16, wherein the capsules are applied as a monolayer.

33. The method according to claim 16, wherein the electronic semiconductor chip is an optoelectronic semiconductor chip.

34. The method according to claim 16, wherein the carrier is a QFN chip housing.
